(19) United States
(12) Patent Application Publication
(10) Pub. No.: US 2002/0138807 A1
(43) Pub. Date: Sep. 26, 2002

(54) Optimum UMTS modem

(76) Inventor: Quang Nguyen, Allentown, PA (US)

Correspondence Address: ICOMM TECHNOLOGIES INC, 7720-S12 MAIN ST., SUITE #252, FOGELSVILLE, PA, 18051, US

(21) Appl. No.: 09/681,360

(22) Filed: Mar. 26, 2001

(51) Int. Cl. H03M 13/03

(52) U.S. Cl. 714/792

(57) ABSTRACT

The present invention encompasses several improved methods and architecture of an UMTS modem for delivering optimum high-speed broadband information, commerce and multimedia entertainment services to mobile users via fixed, wireless and satellite IP networks. The present invention utilizes Turbo Codes baseband processor for optimum performance in decoding received data in limited power and noisy environments. The present invention provides a method for dividing the high-speed bit-stream into multiple slow-speed sub bit-streams, and also dividing the UMTS broadband channel into multiple sub-channels for transmitting each sub bit-stream in the assigned adjacent sub-channels, and the uses of the Orthogonal Frequency Division Multiplexing method implemented by N-point complex FFT/iFFT processor in which it effectively divides the broadband high-speed channel into multiple slow-speed N sub-channels where multiple adjacent channels transmit their carriers' frequency which are orthogonal to each other. Also, when M is smaller than N, channels hopping can be done by reassigning a bit-stream to another sub-channel slot.

### CROSS REFERENCE TO RELATED APPLICATION

### REFERENCED-APPLICATIONS

This patent is based on the development of IP core product for 3G wireless mobile communications by I Comm Technologies, Inc. This patent is related to U.S. patent application Ser. No. 09/681 093 entitle “Turbo Codes Decoder”.

### BACKGROUND OF INVENTION

1. Field of the Invention

This invention relates to UMTS Modem for 3G Wireless Mobile Communications; and more particularly, to a very high speed UMTS Modem using Turbo Codes Encoder/Decoder and channels hopping with Orthogonal Frequency Division Multiplexing method implemented by complex FFT/iFFT processors for multimedia Data, Voice, VolP in wireless Internet applications.

2. Description of the Prior Art

UMTS stands for Universal Mobile Telecommunications System. UMTS is a part of the IMT-2000, a global family of 3G mobile communications systems delivering high-value broadband information, commerce and multimedia entertainment services to mobile users via fixed, wireless and satellite IP networks. Modem stands for modulation and demodulations. When a base station sending digital information to the terminal handset, the modem at the base station converts the digital data into analog signal and transmits it over the air, and the terminal handset modem receives the signal and converts the analog signal back into digital data. As shown in FIG. 1. digital data from the MAC layer 15 is shifted into the UMTS modem transmitter where data is encoded for error-correction, then modulated and sent to the analog front-end 16 for transmitting over the air. Received signal from the analog front-end 16 enters the UMTS modem receiver 13 where it is demodulated by a baseband processor, then shifted to the MAC layer 15. The Turbo Codes baseband processor is used to encode data and to reconstruct the corrupted and noisy received data and to improve BER data throughput in a limited power and noisy environment. The Orthogonal Frequency Division Multiplexing is a technique to divide the broadband channel into sub-channels where multiple adjacent channels transmit their carriers' frequency which are orthogonal to each other, the sum of all carriers can be transmitted over the air to the receiver where each channel's carrier can be separated without loss of information due to interferences. FIG. 2. shows an example of an 8-PSK constellations where each group of 3-bit data is mapped in to a point with an in-phase (I) and quadrature (Q) coordinates.

### SUMMARY OF INVENTION

The present invention provides improved methods and architecture of an UMTS modem for delivering optimum high-speed broadband information, commerce and multimedia entertainment services to mobile users via fixed, wireless and satellite IP networks. The present invention utilizes Turbo Codes baseband processor for optimum performance in decoding received data in limited power and noisy environments. The invention presents a method to divide the UMTS broadband into multiple sub-channels and the uses of an Orthogonal Frequency Division Multiplexing method implemented by N-point complex FFT/iFFT processors in which it effectively divides the broadband high-speed channel into multiple slow-speed N sub-channels where multiple adjacent channels transmit their carriers' frequency which are orthogonal to each other. The high-speed bit-stream is also sub-divided into multiple slow-speed sub bit-streams. An example, the total broadband channel capacity is R-Mbps, then the slower sub-channel capacity S-Mbps is equal to (R-Mbps)/N. Therefore, it is most advantageous for the Turbo Codes baseband processor since it performs much better in slower bit rate with more number of iterations. The present invention utilizes an M-bit serial-to-parallel (S/P) converter to sub-divides the input high-speed R-Mbps bit-stream into multiple M slow-speed S-Mbps bit-streams where each bit-stream will be transmitted in the assigned channel. Each bit-stream is encoded one bit per cycle with the Turbo Codes encoder and then mapped into an 8-PSK constellation point where its I and Q components are mapped into the real and imaginary part of the a complex iFFT point. Since M is less than or equal to N, channel hopping can be done by assigning a bit-stream to a new channel once its current channel getting noisy. Accordingly, several objects and advantages of the present invention are:

To deliver high-quality, high-speed broadband information to wireless IP network.

To utilize Turbo Codes baseband processor, rate ⅓, 8-state SISO Log-MAP, for optimum performance in decoding received data.

To utilize an M-bit serial-to-parallel (S/P) converter to sub-divide the input high-speed bit-stream into multiple M slow-speed bit-stream.

To utilize an Orthogonal Frequency Division Multiplexing method implemented by N-point complex FFT/iFFT processor to sub-divide the broadband high-speed channel into multiple slow-speed N sub-channels.

To implement channel hopping to re-assign new channel once the old channel getting noisy.

To utilize guard-interval (GI) addition to minimize intersymbol interferences.

Still further objectives and advantages will become apparent to one skill in the art from a consideration of the ensuing examples, descriptions and accompanying drawings.

### BRIEF DESCRIPTION OF DRAWINGS

1. An UMTS Modem System Block Diagram (Prior Art).

FIG. 2. An 8-PSK Constellations (Prior Art).

FIG. 3. An UMTS Modem Transmitter Functional Block Diagram.

FIG. 4. An UMTS Modem Receiver Functional Block Diagram.

### DETAILED DESCRIPTION

As shown in FIG. 1. an UMTS modem 11 comprises of an modem transmitter 12 for modulating digital data and sending signal over the air, a modem receiver 13 for demodulating received signal and converting it into digital data, and an AFC Clock Recovery circuitry for recovering clock and synchronization.

### UMTS Modem Transmitter

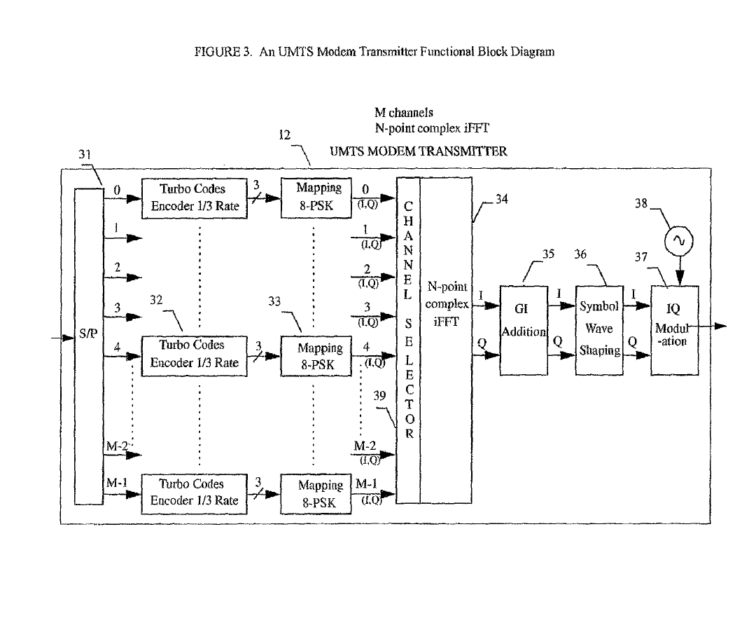

As shown in FIG. 3. an UMTS modem transmitter 12 comprises of an M-bit serial-to-parallel (S/P) converter 31 to convert input bit-stream into an M number of sub bit-streams, an M number of Turbo Codes encoder 32 with coding rate ⅓ and constraint length K=4 corresponding to each bit-stream, an M number of Mapper 33 for 8-PSK modulation corresponding to each channel, a Channel Selector for assigning each bit-stream to a sub-channel, an N-point complex iFFT processor 34 for implementing multiple sub-channels with Orthogonal Frequency Division Multiplexing method, a guard interval (GI) adder 35 for adding guard interval, a Symbol Wave Shaper 36, and an IQ Modulator 37 for modulation the transmit signal with a carrier, a Carrier generator 38 produces carrier frequency.

As shown in FIG. 3. and FIG. 1., the UMTS modem transmitter 12 functions effectively as follows:

High-speed R-Mbps input serial data is shifted into the M-bit serial-to-parallel (S/P) converter 31 to generate the slow-speed S-Mbps M serial sub bit-streams (labeled from 0 to M−1).

Each sub bit-stream is shifted serially into its own Turbo Codes encoder 32, with coding rate ⅓ and constraint length K=4, one bit per cycle where it is converted into a 3-bit symbol output (one data bit and two parity bits).

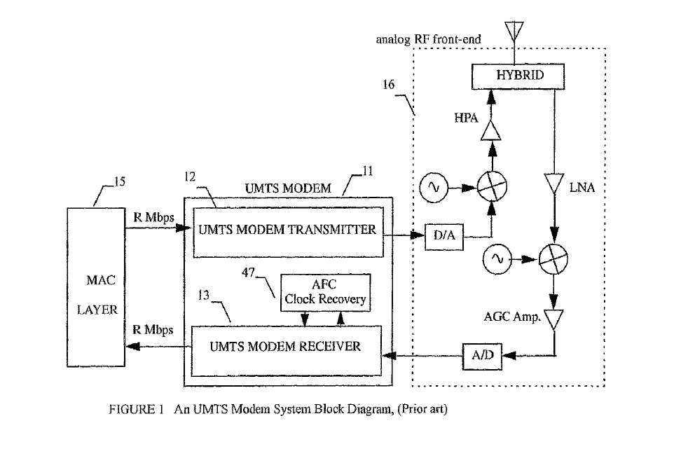

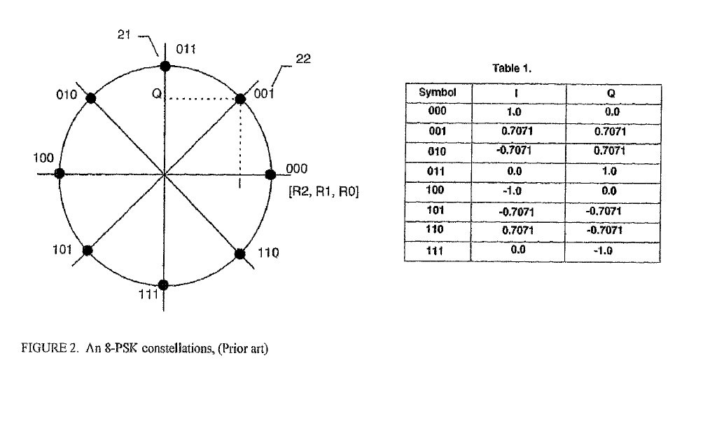

The 3-bit symbol 22 is shifted into the 8-PSK Mapper 33 where it is mapped into a constellation point 21 as shown in FIG. 2. The values of its I and Q components are selected from the Table 1. The output of the 8-PSK Mapper 33 is a set of (I,Q) values corresponds to the Real and Imaginary parts of a point in the complex iFFT processor.

The (I,Q) values are shifted into the Channel Selector 39 where each set of (I,Q) is assigned to a point in the N-point complex iFFT processor. When channel hopping is required, the Channel Selector 39 can re-assign a new point for that requested set of (I,Q).

The complex iFFT Processor 34 perform the invert complex fast Fourier transform (iFFT) to produce N complex samples which are then separated into an I sequence and a Q sequence of N samples correspond the real and imaginary parts.

The I and Q sequences are shifted completely through the GI Adder 35 where the guard interval is added to each I and Q sequences.

The I and Q sequences are then shifted completely through the Symbol Wave Shaper 36 where the I and Q sequences are modified by a symbol wave-shaper FIR filter.

The I and Q sequences are then shifted completely through the IQ Modulator 37 where the I sequence is modulated with Sine carrier 38, and the Q sequence is modulated with a Cosine carrier 38. The summation of the modulated I and Q sequences produces the transmit signal output.

### UMTS Modem Receiver

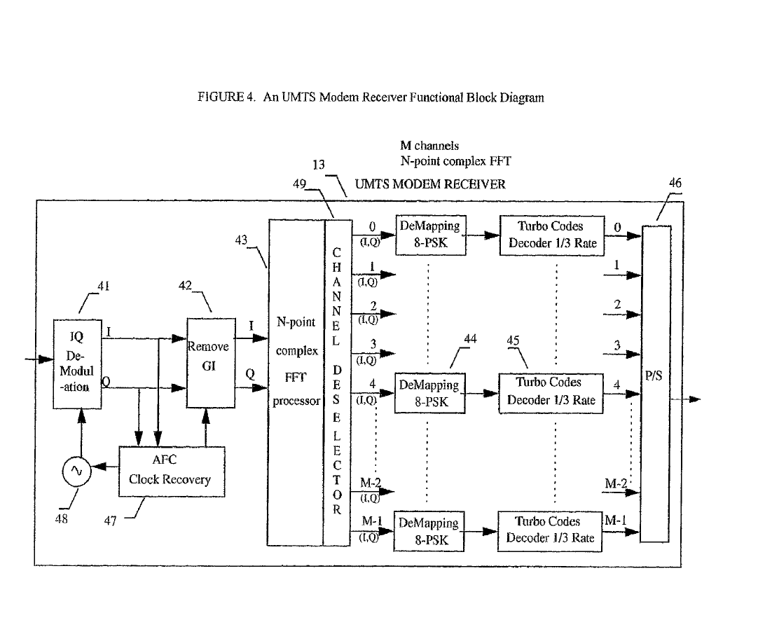

As shown in FIG. 4. an UMTS modem receiver 13 comprises of an IQ demodulator 41 for demodulating the receive signal with a carrier, a local carrier generator 48 produces carrier frequency, an AFC Clock circuitry 47, a guard interval (GI) remover 42 for deleting guard interval, an N-point complex FFT processor 43 for implementing multiple sub-channels with Orthogonal Frequency Division Multiplexing method, an M number of de-Mapper 44 for 8-PSK demodulation corresponding to each channel, an M number of Turbo Codes Decoder baseband processor 45 with coding rate ⅓ and constraint length K=4 corresponding to each bit-stream, an M-bit parallel-to-serial (P/S) converter 46 to convert the M input sub bit-streams into a final bit-streams output.

As shown in FIG. 4. and FIG. 1., the UMTS modem receiver 13 functions effectively as follows:

Receive signal entering the IQ Demodulator 41 is demodulated with a local carrier 48 to produce the I and Q sequences of N samples.

The I and Q sequences are shifted completely through the GI Remover 42 where the guard interval is remove from each I and Q sequence.

The I and Q sequences are then shifted completely into the N-point complex FFT Processor 43. The FFT Processor 43 performs complex Fast Fourier Transform (FFT) for the I and Q sequences of N samples to convert them into N complex points data.

The Channel De-selector 49 then selects each complex point data for each set of (I,Q) values correspond to each of the M bit-streams.

Each set of (I,Q) is shifted into the 8-PSK De-Mapper 44 where it is convert into a soft-decision value output.

The soft-decision value data is shifted into the Turbo Codes Decoder baseband processor 45, where data is iteratively decoded until a final decision hard-decoded bit is produced for the output correspond to each bit-stream.

The hard-decoded output bit is latched into the M-bit parallel-to-serial (P/S) 46, where the all the M-bit data is serially shifted to the output.

1. An optimum units modem for multimedia data, voice, VolP in wireless internet applications comprising of:
an UMTS modem transmitter;
an UMTS modem receiver;
an N-point complex FFT processor and an N-point complex iFFT processor for implementing the multiple sub-channels with Orthogonal Frequency Division Multiplexing method;
a Turbo Codes baseband processor for optimum performance in decoding of noisy receive data, and encoding transmit data;
an 8-PSK Mapper for mapping a 3-bit symbol into a point on the 8-PSK constellations with the I and Q component values;
an 8-PSK De-mapper for converting the received set (I,Q) values from the complex FFT processor into soft-decision values for the Turbo Code baseband processor;
an M-bit serial-to-parallel (S/P) converter for segmenting the input bit-stream into an M number of sub bit-streams;
an M-bit parallel-to-serial (P/S) converter for shifting the decoded data to the output;
a Channel Selector and a Channel De-selector for assigning bit-streams into sub-channels, and also controlling the channel hopping function;
a GI adder and a GI remover for adding and removing guard intervals from the I and Q sequences of samples;
a Symbol wave shaper;
an IQ Modulator for modulating the I and Q sequences of samples and adding them into a transmit signal;
an IQ Demodulator for demodulating the receive signal and producing the I and Q sequences of N samples; and
an AFC Clock Recovery circuitry for clock synchronization.

2. The UMTS modem system of claim cl, wherein the Turbo Codes baseband processor uses SISO 8-state Log-MAP decoder for high-speed and optimum decoding a plurality of sequences of the receive samples.

3. The UMTS modem system of claim c1, wherein the 8-PSK De-mapper produces soft-decision values output.

4. The UMTS modem system of claim c1, wherein the complex FFT/iFFT processors sub-divide the UMTS broadband channel into multiple sub-channels by using the Orthogonal Frequency Division Multiplexing method.

5. The UMTS modem system of claim c1, wherein the M-bit serial-to-parallel (S/P) converter sub-divides the high-speed R-Mbps input to generate the multiple slow-speed S-Mbps M sub bit-streams; where S-Mbps is equal to R-Mbps divide by N.

6. The UMTS modem system of claim c1, further provides a method to divide the UMTS broadband into multiple sub-channels and the uses of an Orthogonal Frequency Division Multiplexing method implemented by N-point complex FFT/iFFT processors where multiple adjacent channels transmit their carriers' frequency which are orthogonal to each other.

7. The UMTS modem system of claim c1, further provides a method to divide high-speed bit-stream into multiple slow-speed sub bit-streams for transmitting over the sub-channels.

8. The UMTS modem system of claim c1, further provides a method to control channels hopping by re-assign bitstream into another sub-channel.

9. A method for UMTS modem transmitting a plurality of high-speed digital information generated from a MAC layer into wireless IP networks comprising the steps of:
(1) sub-divide the high-speed R-Mbps input serial data by shifting it into the M-bit serial-to-parallel (S/P) converter to generate the multiple slow-speed S-Mbps M sub bit-streams;
(2) encode each bit of each bit-streams independently with a Turbo Codes encoder, with coding rate ⅓ and constraint length K=4, to generate a 3-bit symbol (one data bit and two parity bits);
(3) map the 3-bit symbol into an 8-PSK constellations points to select the values of its I and Q components;
at this point, all the sub bit-streams are done the same as the above step (2), (3);
(4) select a point in the N-point complex iFFT and map the I component into its real part and the Q component into its imaginary par accordingly;
(5) perform the invert complex N-point Fast Fourier Transform to produces the two I and Q sequences of N samples corresponding to the real and imaginary of the complex iFFT products;
(6) add the guard interval to the I and Q sequences of N samples;
(7) modify the I and Q sequences of N samples with and FIR filter Symbol wave shaper;
(8) modulate the I sequence with a Sine carrier, and the Q sequence with a Cosine carrier;
(9) sum the two modulated I and Q with an adder to produce the transmit signal.

10. A method for UMTS modem receiving a plurality of high-speed digital information received from the wireless IP networks comprising the steps of:
(1) demodulate the receive signal with a local carrier to produce the I and Q sequences of N samples;
(2) remove the guard interval from the I and Q sequences of N samples;
(3) perform the complex N-point Fast Fourier Transform on the I and Q sequences of N samples to convert them into N complex points data;
(4) de-selector each of N complex point data for each set of (I,Q) values correspond to each of the M bit-streams;
(5) de-map each of the M complex point (I,Q) based on an 8-PSK constellations to produce soft-decision values;
(6) decode the soft-decision value with the Turbo Codes Decoder baseband processor, where data is iteratively decoded until a final decided hard-decoded bit is produced for the output correspond to each bit-stream; at this point, all bit-streams are done with steps (5) and (6);
(7) latch all M decoded bits into the parallel-to-serial converter and shift out to the output.
